(19) United States
(12) Patent Application Publication
(10) Pub. No.: US 2012/0305950 A1
(43) Pub. Date: Dec. 6, 2012

(54) DISPLAY APPARATUS

(75) Inventors: Noriyuki Shikina, Ichihara-shi (JP); Kiyofumi Sakaguchi, Miura-gun (JP)

(73) Assignee: CANON KABUSHIKI KAISHA, Tokyo (JP)

(21) Appl. No.: 13/482,741

(22) Filed: May 29, 2012

(30) Foreign Application Priority Data
Jun. 1, 2011 (JP) 2011-123617(PAT.)

(51) Int. Cl. H01L 27/32; H01L 51/56

(52) U.S. Cl. 257/88; 438/29; 257/E51.018; 257/E27.119; 257/40

(57) ABSTRACT

Disclosed is a method of making a display apparatus including a step of forming an underlying layer on a substrate, the underlying layer having a protrusion; and a step of depositing a material of a lens portion so as to form a film having a shape that follows a shape of the underlying layer.

### BACKGROUND OF THE INVENTION

1. Field of the Invention

The present invention relates to a display apparatus using an organic electroluminescent element.

2. Description of the Related Art

In recent years, display apparatuses have been actively developed that use an organic electroluminescent element including an organic compound layer interposed between a pair of electrodes. Such an organic electroluminescent element has a problem in that the light extraction efficiency is low. To increase the light extraction efficiency, Japanese Patent Laid-Open No. 2004-039500 discloses a structure in which a microlens array composed of a resin is disposed on a protection film on an organic electroluminescent element.

Japanese Patent Laid-Open No. 2004-039500 describes a method of forming the microlens array, which includes a step of applying a resin, a step of making a mold of the microlens array be in close contact with the resin, and a step of curing the resin.

In the method described in Japanese Patent Laid-Open No. 2004-039500, it is necessary to perform these complicated steps in addition to a step of forming the organic electroluminescent element.

### SUMMARY OF THE INVENTION

The present invention provides a simple method of forming a lens in a display apparatus.

According to a first aspect of the present invention, a method of making a display apparatus, which includes an organic electroluminescent element and a lens portion, includes a step of forming an underlying layer on a substrate, the underlying layer including a protrusion; a step of forming the organic electroluminescent element on the protrusion of the underlying layer; and a step of forming the lens portion on the organic electroluminescent element, the lens portion converging light emitted by the organic electroluminescent element. The step of forming the lens portion is a step of depositing a material of the lens portion so as to form a film having a shape that follows a shape of the underlying layer.

According to a second aspect of the present invention, a display apparatus includes an underlying layer formed on a substrate and having a protrusion; an organic electroluminescent element formed on the protrusion of the underlying layer; and a lens portion formed on the organic electroluminescent element, the lens portion converging light emitted by the organic electroluminescent element. The lens portion has a shape that follows a shape of the underlying layer.

According to a third aspect of the present invention, a display apparatus includes an underlying layer formed on a substrate and having a protrusion; an organic electroluminescent element formed on the protrusion of the underlying layer; and a lens portion formed on the organic electroluminescent element, the lens portion converging light emitted by the organic electroluminescent element. A surface of the lens portion has a protruding surface at a position corresponding to that of the protrusion of the underlying layer.

With the present invention, a lens can be easily formed in a display apparatus.

Further features of the present invention will become apparent from the following description of exemplary embodiments with reference to the attached drawings.

### BRIEF DESCRIPTION OF THE DRAWINGS

FIGS. 1A to 1C are schematic views illustrating an example of a display apparatus according to a first embodiment of the present invention.

FIGS. 2A to 2E are schematic views illustrating a method of making the display apparatus according to the first embodiment of the present invention.

FIG. 3 is a schematic view illustrating another example of the display apparatus according to the first embodiment of the present invention.

FIGS. 4A and 4B are schematic views illustrating an example of a display apparatus according to a second embodiment of the present invention.

FIG. 5 is a schematic view illustrating an example of a display apparatus according to a third embodiment of the present invention.

### DESCRIPTION OF THE EMBODIMENTS

Hereinafter, embodiments of a display apparatus according to the present invention will be described with reference to the drawings. Well-known or publicly known technologies in the technical field may be used for portions that are not described or illustrated in the present specification. The present invention is not limited to the embodiments described below.

### First Embodiment

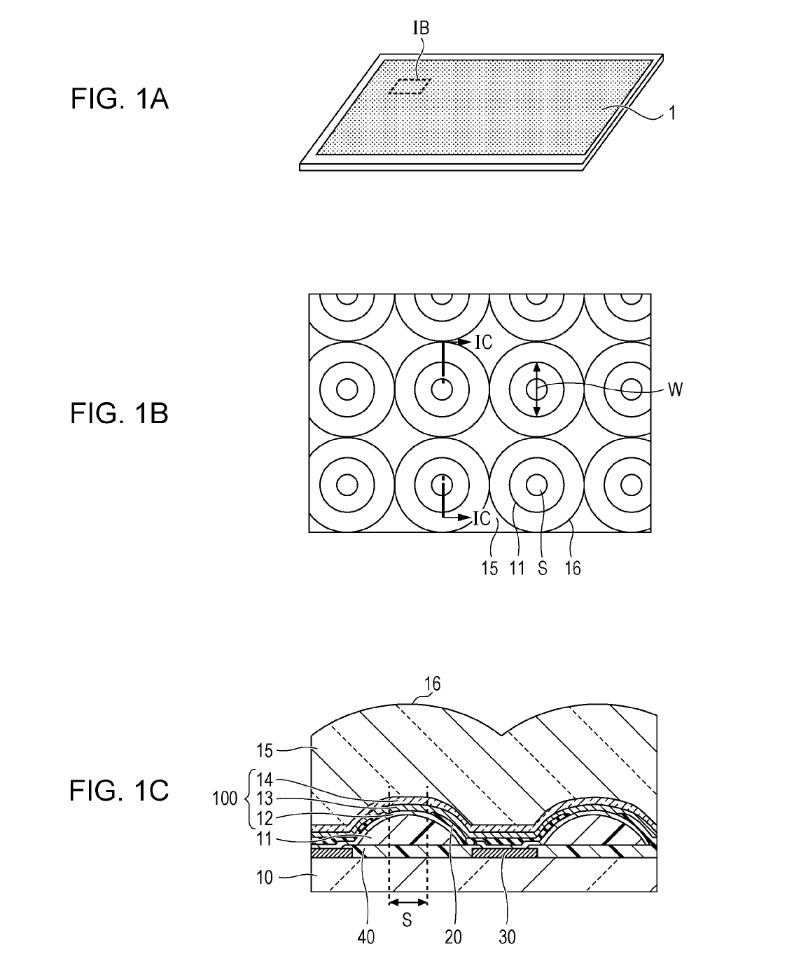

FIG. 1A is a schematic perspective view of a display apparatus according to a first embodiment of the present invention. The display apparatus of the present embodiment includes a plurality of pixels (not shown) each of which including an organic electroluminescent element. The plurality of pixels are arranged in a matrix pattern, thereby forming a display region 1. Here, the term “pixel” refers to a region corresponding to a light-emitting region of a light-emitting element. In the display apparatus of the present embodiment, the light-emitting element is an organic electroluminescent element, and an organic electroluminescent element for a single color is disposed in each of the pixels. Examples of the color of light emitted by the organic electroluminescent elements include red, green, and blue; and may include yellow, cyan, and white. The colors are not particularly limited as long as the number of the colors is larger than one. A plurality of pixel units are arranged in the display apparatus of the present embodiment. Each pixel unit includes a plurality of pixels that emit light of different colors (for example, a pixels that emits red light, a pixel that emits green light, and a pixel that emits blue light). Here, the term “pixel unit” refers to the smallest unit that is capable of emitting a desired light by combining the colors of light emitted by the pixels.

FIG. 1B is an enlarged schematic top view of a region surrounded by broken line IB of FIG. 1A. FIG. 1C is a partial sectional schematic view taken along line IC-IC of FIG. 1B. An underlying layer 11 having a protruding shape is formed on a substrate 10, and an organic electroluminescent element 100 is disposed on the underlying layer 11. The organic electroluminescent element 100 includes a first electrode 12, an organic compound layer 13, and a second electrode 14, which are stacked. A lens portion 15 is formed so as to cover the organic electroluminescent element 100. The lens portion 15 includes a lens 16 that converges light emitted from a light-emitting region S of the organic electroluminescent element 100 and that emits the light to the outside. The light-emitting region S is a region in which the organic compound layer 13 is sandwiched between the first electrode 12 and the second electrode 14 in a direction perpendicular to the substrate 10. In FIG. 1C, the light emitting region S corresponds to an opening in an insulation layer 20. The organic electroluminescent element 100 is driven by a transistor (not shown) disposed on the substrate 10. For this purpose, the transistor and the first electrode 12 are connected to each other through a wiring line 30. A passivation layer 40 is disposed on the transistor. The passivation layer 40 has an opening above the wiring line 30 so that the transistor and the first electrode 12 can be connected to each other.

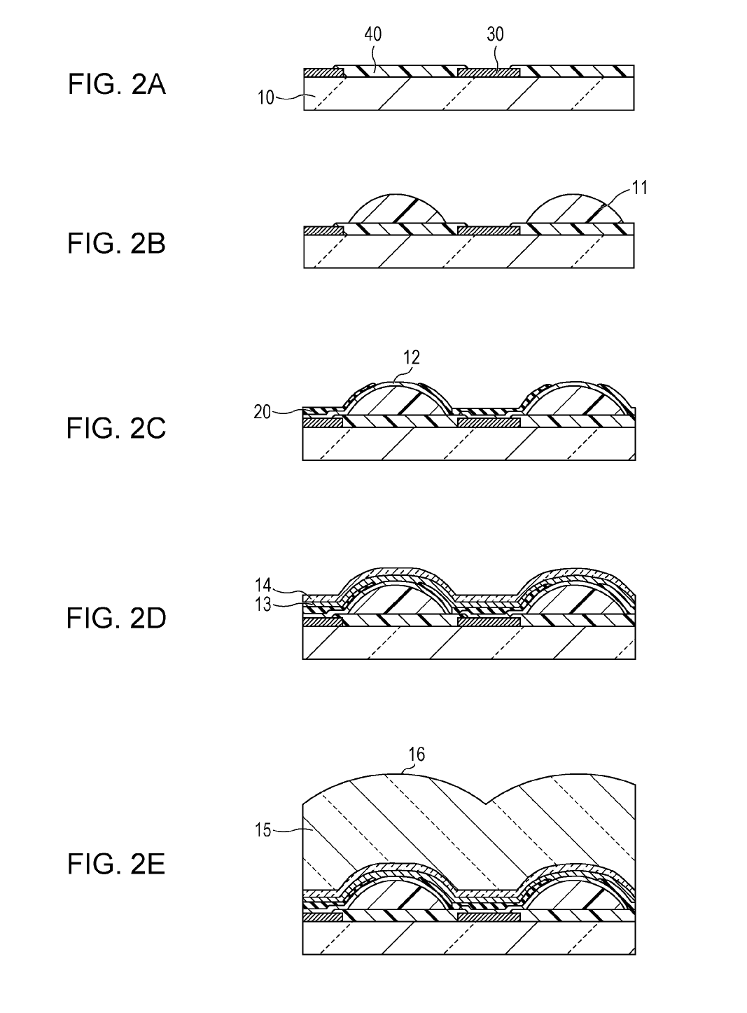

Next, referring to FIGS. 2A to 2E, a method of making a display apparatus of the present embodiment will be described. FIGS. 2A to 2D, which correspond to FIG. 1C, are schematic sectional views illustrating steps of making the display apparatus of the present embodiment.

First, as illustrated in FIG. 2A, a driving circuit (not shown), such as a transistor, is formed on the substrate 10. The wiring line 30 for connecting the driving circuit to the first electrode 12, which will be described below, is formed on the substrate 10. The passivation layer 40, which has an opening over the wiring line 30, is formed on the transistor.

The substrate 10 may be made from a glass, quartz, or the like. The wiring line 30 may be a metal layer composed of aluminium, silver, and the like. The passivation layer 40 may be made from an inorganic material such as polyimide resin, an acrylic resin, or an epoxy resin; or may be made from an inorganic material such as silicon nitride.

Next, as illustrated in FIG. 2B, the underlying layer 11 having a protrusion is formed on the passivation layer 40. The underlying layer 11 may be made from a resin material such as a polyimide resin, an acrylic resin, or an epoxy resin. The underlying layer 11 is formed as follows. First, a resin material of the underlying layer 11 is applied to a surface of the substrate 10. Next, the resin material is prebaked. Next, gradation exposure using a gradation mask or the like and developing are performed, and thereby patterning is performed so that a protrusion is formed in a region in which an organic electroluminescent element is to be disposed. Subsequently, the resin material remaining on the substrate 10 is postbaked, and thereby the underlying layer 11 having the protrusion is formed. By controlling the gradation of exposure, the protrusion formed on the underlying layer 11 may have a hemispherical shape or a quadrangular pyramidal frustum shape as will be described in a second embodiment. When forming a hemispherical protrusion on the underlying layer 11, the radius of curvature of the hemisphere can be increased or decreased by controlling the gradation of exposure. The number of protrusions of the underlying layer 11 included in one pixel may be one or may be larger than one. In the latter case, each of the protrusions may be provided with a light-emitting region of the organic electroluminescent element.

The width of the underlying layer 11, which is denoted by W in FIG. 1B, is preferably in the range of 5.0 to 30 μm and more preferably smaller than a pixel pitch. In FIG. 2B, adjacent underlying layers 11 are not continuous with each other. However, adjacent underlying layers 11 may be continuously formed as long as they have protrusions on the surfaces thereof. The height of the underlying layer 11 is defined as the distance from the substrate 10 to a position on the surface of the underlying layer 11 that is farthest from the substrate 10. To be specific, the height is preferably in the range of 1.0 to 15 μm and more preferably in the range of 2.0 to 10 μm. The pitch of the underlying layer 11 is defined as the distance between the central axes of a pair of adjacent underlying layers 11. This pitch is the same as the pixel pitch. As described above, when there is a plurality of protrusions of the underlying layer 11 in one pixel, the pitch of the underlying layer 11 is equal to or smaller than the pixel pitch. When the underlying layer has a hemispherical shape as illustrated in FIG. 2B, the radius of curvature of the protrusion is preferably in the range of 3.0 to 100 μm and more preferably in the range of 5.0 to 50 μm.

Next, as illustrated in FIG. 2C, the first electrode 12 is formed on the underlying layer 11. The first electrode 12 is continuously formed over the top portion of the underlying layer 11 and the wiring line 30. The first electrodes 12 of a pair of adjacent organic electroluminescent elements are separated from each other. The insulation layer 20 is formed on the first electrode 12 so as to have an opening above a part of the first electrode 12 (at the top of the underlying layer 11). The opening corresponds to the light-emitting region S of the organic electroluminescent element. The area of the light-emitting region S is preferably equal to or smaller than ½ of the area of the bottom surface of the protrusion of the underlying layer 11 and more preferably equal to or smaller than ¼ of the area of the bottom surface. The insulation layer 20 prevents a short circuit between the first electrode 12 and the second electrode 14 (described below), which might be caused by a foreign substance.

The first electrode 12 is made from a metal material having electroconductivity and high reflectance such as silver. The first electrode 12 may be a stack of a layer composed of such a metal material and a layer composed of a transparent electroconductive material such as indium tin oxide (ITO) or indium zinc oxide.

The insulation layer 20 may be made from a material the same as that of the passivation layer 40. The film thickness of the insulation layer 20 is in the range of 0.5 to 2.0 μm. The insulation layer 20 is patterned by photolithography so that the opening in the first electrode 12 is exposed.

Next, as illustrated in FIG. 2D, the organic compound layer 13 is formed over the opening in the first electrode 12 and on the insulation layer 20. Then, the second electrode 14 is formed on the organic compound layer 13.

The organic compound layer 13 includes at least a light-emitting layer. The organic compound layer 13 may further include one or more layers such as a positive hole transport layer and an electron transport layer. The light-emitting layer, the positive hole transport layer, and the electron transport layer may be made from a known material. In the case where two adjacent pixels emit light of the same color, the organic compound layer 13 may be integrally formed over the two pixels. In the case where two adjacent pixels emit light of different colors, at least the organic compound layers are independently formed on the pixels. In the latter case, by selecting an appropriate material for the light-emitting layer, the light-emitting layer may be integrally formed over the pixels that emit light of different colors.

The second electrode 14 is a common electrode for a plurality of pixels (organic electroluminescent elements 100). The second electrode 14 is light-transmissive or semi-reflective so that light emitted by the organic compound layer 13 can be emitted to the outside of the element. To be specific, when a semi-reflective second electrode 14 is used to increase an interference effect in the element, the second electrode 14 is formed from an electroconductive metal material such as a silver alloy so as to have a film thickness in the range of 2.0 to 50 nm. Here, the term “semi-reflective” refers to a characteristic with which a part of light generated in an element is reflected and the remaining part is transmitted, which corresponds to a reflectance in the range of 20 to 80% for visible light. When a light-transmissive second electrode 14 is used, the second electrode 14 is formed from a transparent electroconductive material such as indium tin oxide (ITO) or indium zinc oxide so as to have a film thickness in the range of 50 to 150 nm. Here, the term “light-transmissive” refers to a characteristic having a transmittance equal to or higher than 80% for visible light. Which of the first electrode 12 and the second electrode 14 is an anode and which of these is a cathode may be appropriately selected.

Next, as illustrated in FIG. 2E, the lens portion 15 for converging light emitted by the organic electroluminescent element is formed on the second electrode 14. The lens portion 15 has a shape that follows the shape of the underlying layer 11 having the protrusion. Here, the term “follow the shape” means that a protruding surface is formed at a position on the lens portion 15 corresponding to that of the protrusion of the underlying layer 11 and a recessed surface is formed at a position on the lens portion 15 under which the underlying layer 11 is not present or at a position on the lens portion 15 corresponding to that of a depression in the underlying layer 11. The protruding surface and the recessed surface of the lens portion 15 may be smoothly connected to each other.

The lens portion 15 may be made from an inorganic material such as silicon nitride (SiN) or silicon oxynitride (SiON). The film thickness of the lens portion 15 is preferably in the range of 0.1 to 20 μm and more preferably in the range of 1 to 10 μm. The lens portion 15 may be formed by vacuum deposition such as CVD, sputtering, or vacuum vapor deposition. The lens portion 15 is formed so as to follow the shape of the underlying layer by depositing the material of the lens portion 15 onto the organic electroluminescent element by vacuum deposition such as CVD, sputtering, or vacuum vapor deposition. That is, by forming the underlying layer 11 having the protrusion, the lens 16 can be easily formed by depositing the material of the lens portion 15 on the underlying layer 11. Moreover, because the lens 16 is formed at a position that is above the protrusion of the underlying layer 11 and that corresponds to the position of the organic electroluminescent element, the amount of displacement between the lens 16 and the organic electroluminescent element is reduced. As illustrated in FIG. 2E, the width of a protrusion of the lens portion 15 (the diameter of the lens 16 of the lens portion 15) may be larger than that of the underlying layer 11. Alternatively, the widths may be the same. Here, the term “lens” refers to a structure that directs light forward by using refraction.

If it is necessary to change the radius of curvature of the lens 16 of the lens portion 15 in accordance with the color of light emitted by the pixel, the radius of curvature of the underlying layer 11 may be changed in accordance with the color. For example, if it is necessary to make the light extraction efficiency of a specific color higher than those of the other colors, gradation exposure may be performed so that the lens 16 of a pixel that emits light of the specific color has a larger radius of curvature. This can be done by increasing the radius of curvature of the underlying layer 11. To be more specific, when a gray tone mask is used as the gradation mask, this can be done by controlling the distance between apertures in the mask. When a half tone mask is used as the gradation mask, this can be done by controlling the light transmittance of the mask.

The lens portion 15 may also serve as a protection layer for protecting the organic compound layer 13 from oxygen and water vapor in the air. As long as the surface of the lens portion 15 has protrusions and depressions that follow the shape of the underlying layer 11, layers of different inorganic materials may be stacked or a layer of an inorganic material and a layer of an organic material may be stacked. The organic material may be a color filter.

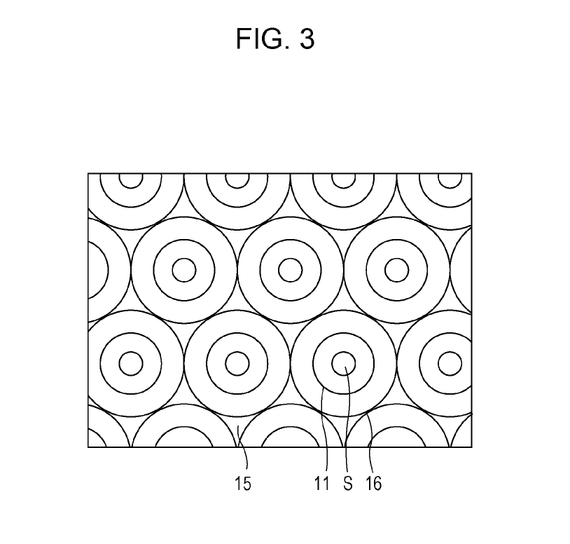

FIG. 3 is a schematic top view of another example of a display apparatus according to the first embodiment. As illustrated in FIG. 3, the underlying layer 11 may be arranged on the substrate 10 in a staggered pattern.

### Second Embodiment

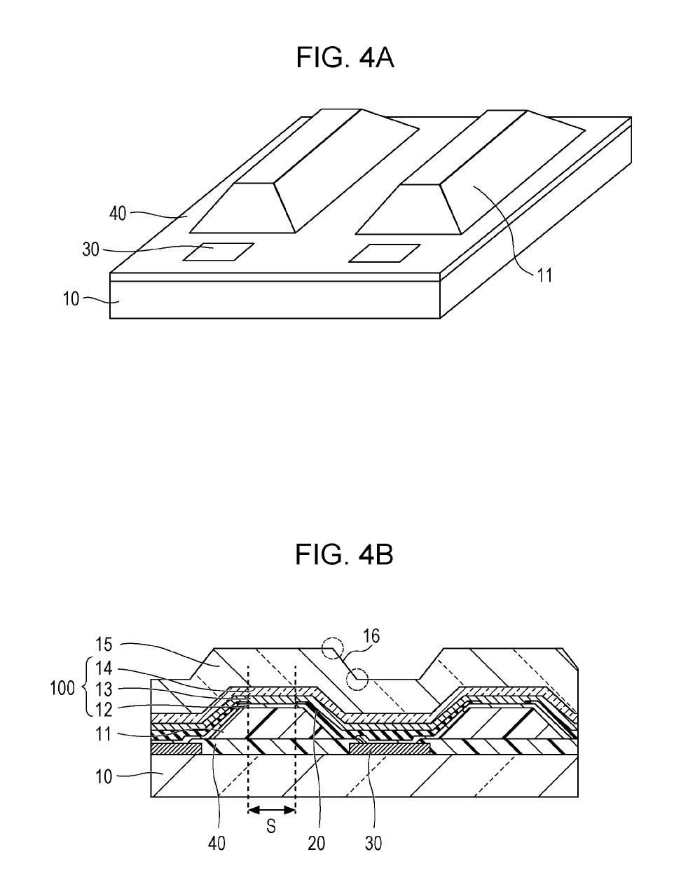

FIGS. 4A and 4B are schematic views of a display apparatus according to a second embodiment. The present embodiment differs from the first embodiment in the shape of the underlying layer 11. To be specific, the shape of the protrusion of the underlying layer 11 of the first embodiment is hemispheric. In contrast, the shape of the protrusion of the underlying layer 11 of the present embodiment is quadrangular-pyramidal-frustum-shaped as illustrated in FIG. 4A.

FIG. 4B is a schematic sectional view of a structure including the underlying layer 11, which has a quadrangular-pyramidal-frustum-shaped protrusion, and an organic electroluminescent element and the lens portion 15 that are stacked on the underlying layer 11. The method of making the underlying layer 11 is the same as that of the first embodiment. The lens portion 15 is formed so as to follow the shape of the underlying layer 11. Therefore, the lens portion 15 has a quadrangular-pyramidal-frustum-shaped protrusion that follows the shape of the underlying layer 11. Inclined surfaces of the quadrangular-pyramidal-frustum-shaped protrusion of the lens portion 15 serve as the lens 16 that refracts light emitted from the organic electroluminescent element and emits the light forward. Inclinations of the inclined surfaces can be increased or decreased by controlling the gradation of exposure. Parts of the lens portion 15 surrounded by broken lines in FIG. 4B may be smoothly curved.

The underlying layer 11 having a quadrangular pyramidal frustum shape illustrated in FIG. 4A is rectangular in top view. View angle characteristics of the underlying layer 11 in the horizontal direction (longitudinal direction) of the substrate 10 and the vertical direction (transversal direction) of the substrate are different from each other. In this case, the underlying layer 11 may be disposed so that the vertical direction of the substrate 10 and the transversal direction of the rectangle are parallel to each other and so that the vertical direction of the substrate 10 and the longitudinal direction of the rectangle are parallel to each other.

The shape of the underlying layer 11 in top view need not be rectangular. Alternatively, the shape may be square, quadrangular, polygonal, or elliptical. That is, the shape of the protrusion of the underlying layer 11 may be hemispherical, hemi-ellipsoidal, quadrangular-pyramidal-frustum-shaped, conical-frustum-shaped, elliptic-conical-frustum shaped, or the like. Such shapes can be obtained by controlling the gradation of exposure when forming the underlying layer 11.

### Third Embodiment

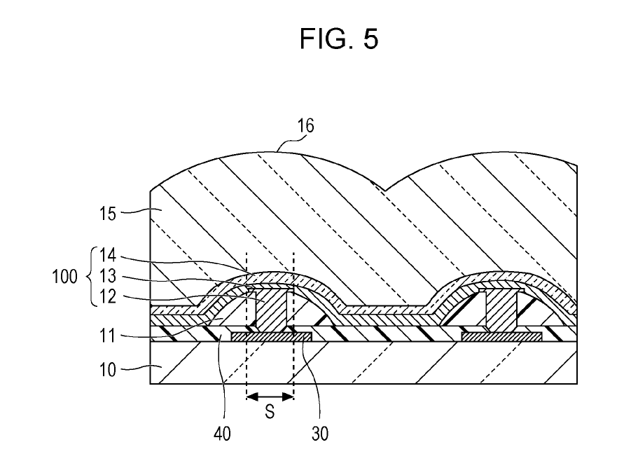

The first embodiment includes the insulation layer 20. However, the insulation layer 20 may be omitted, provided that short circuit between the first electrode 12 and the second electrode 14 can be prevented. FIG. 5 is a partial sectional schematic view of a display apparatus according to a third embodiment.

The present embodiment differs from the first embodiment in the following respects. That is, the protrusion of the underlying layer 11 is disposed over the wiring line 30. An opening, through which the wiring line 30 is exposed, is formed in the protrusion of the underlying layer 11 so that the first electrode 12 is connected to the wiring line 30 through the opening. The first electrode 12 is disposed in the opening formed in the protrusion of the underlying layer 11 and extends to the surface of the protrusion. The first electrode 12 may extend to a position above the surface of the protrusion by a distance that is smaller than the film thickness of the organic compound layer 13.

With this structure, a step of forming the insulation layer 20 can be omitted, so that the number of fabrication steps of the present embodiment can be made smaller than that of the first embodiment.

### Example

Referring to FIGS. 2A to 2E, an example of a method of making a display apparatus according to the first embodiment will be described.

First, as illustrated in FIG. 2A, a TFT driving circuit (not shown) composed of a low-temperature polysilicon was formed on the substrate 10 made of a glass. The wiring line 30 and the passivation layer 40 were formed on the substrate 10. The wiring line 30 was composed of AlNd and connected a TFT driving circuit to the first electrode 12 described below. The passivation layer 40 was composed of a polyimide resin and had an opening over the wiring line 30.

Next, a polyimide resin was applied to the passivation layer 40 and prebaked. Gradation exposure and developing were performed by using a half tone mask, so that a protrusion having a hemispherical cross section along a plane perpendicular to the substrate 10 was formed between the wiring lines 30. The entirety of the underlying layer 11 was postbaked, thereby forming the underlying layer 11 illustrated in FIG. 2B. Patterning was performed so that the underlying layer 11 of each pixel had a thickness of 3.0 μm and a radius of curvature of 6.0 μm.

Next, as illustrated in FIG. 2C, ITO/AlNd were deposited on the underlying layer 11 by sputtering so as to respectively have thicknesses of 38 nm/100 nm, and the ITO/AlNd were patterned for each pixel, thereby forming the first electrode 12.

Next, as illustrated in FIG. 2C, a SiN film having a film thickness of 300 nm was formed so as to cover the first electrode 12. An opening was formed in the SiN film so that the first electrode 12 was exposed, thereby forming the insulation layer 20. The opening had a diameter of 4.0 μm. The insulation layer 20 was subjected to ultrasonic washing using isopropyl alcohol (IPA) and to boiling washing, and was dried.

Next, as illustrated in FIG. 2D, UV/ozone washing was performed, and then the organic compound layer 13 was deposited by vacuum vapor deposition.

First, a hole transport layer having a thickness of 90 nm was formed on each pixel. Next, a red-light-emitting layer, a green-light-emitting layer, and a blue-light-emitting layer, respectively having thicknesses of 30, 40, and 25 nm were formed by using a shadow mask. Next, an electron transport layer common to all pixels was formed so as to have a thickness of 10 nm. Subsequently, an electron injection layer common to all pixels was formed so as to have a thickness of 40 nm.

Next, as illustrated in FIG. 2D, after the electron injection layer had been formed on the substrate 10, the substrate 10 was moved to sputtering apparatus in a vacuum atmosphere, and silver and indium zinc oxide were deposited respectively with thicknesses of 10 and 50 nm, thereby forming the second electrode 14.

Next, as illustrated in FIG. 2E, a SiN film was formed as the lens portion 15 on the second electrode 14. The SiN film was formed so as to have a thickness of 6.0 μm by using a CVD apparatus. Protrusions and depressions corresponding to the shape of the underlying layer 11 were formed on the SiN film, so that the underlying layer 11 had a sectional shape illustrated in FIG. 2E. Because a SiN film tends to be deposited isotropically, the shape illustrated in FIG. 2E (having a radius of curvature of 12 μm) was formed.

In the display apparatus made by the method described above, the lens 16 was formed on the SiN film so that the display apparatus had a front luminance of about 2.5 times higher and a light extraction quantity of about 1.5 times larger than those of an display apparatus having a flat underlying layer.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-123617 filed Jun. 1, 2011, which is hereby incorporated by reference herein in its entirety.

What is claimed is:

1. A method of making a display apparatus including an organic electroluminescent element and a lens portion, the method comprising:
a step of forming an underlying layer on a substrate, the underlying layer including a protrusion;
a step of forming the organic electroluminescent element on the protrusion of the underlying layer; and
a step of forming the lens portion on the organic electroluminescent element, the lens portion converging light emitted by the organic electroluminescent element,
wherein the step of forming the lens portion is a step of depositing a material of the lens portion so as to form a film having a shape that follows a shape of the underlying layer.

2. The method of making a display apparatus according to claim 1,
wherein the step of forming the lens portion is a step of depositing the material of the lens portion so as to form a film by vacuum deposition.

3. The method of making a display apparatus according to claim 1,
wherein the step of forming the underlying layer includes a step of performing gradation exposure and developing of a material of the underlying layer.

4. The method of making a display apparatus according to claim 1,
wherein the step of forming an underlying layer includes a step of forming the underlying layer so that a protrusion formed on the underlying layer has a hemispherical shape.

5. The method of making a display apparatus according to claim 1,
wherein the step of forming an underlying layer includes a step of forming the underlying layer so that a protrusion formed on the underlying layer has a quadrangular pyramidal frustum shape.

6. The method of making a display apparatus according to claim 1,
wherein the step of forming the organic electroluminescent element includes:
a step of forming a first electrode on the underlying layer,
a step of forming an insulation layer on the first electrode so as to have an opening above a part of the first electrode,
a step of forming an organic compound layer over the opening above a part of the first electrode, and
a step of forming a second electrode on the organic compound layer.

7. A display apparatus comprising:
an underlying layer formed on a substrate and having a protrusion;
an organic electroluminescent element formed on the protrusion of the underlying layer; and
a lens portion formed on the organic electroluminescent element, the lens portion converging light emitted by the organic electroluminescent element,
wherein the lens portion has a shape that follows a shape of the underlying layer.

8. The display apparatus according to claim 7,
wherein a protrusion formed on the underlying layer has a hemispherical shape.

9. The display apparatus according to claim 7,
wherein a protrusion formed on the underlying layer has a quadrangular pyramidal frustum shape.

10. The display apparatus according to claim 7,
wherein a width of the underlying layer is in a range of 5.0 to 30 μm.

11. The display apparatus according to claim 7,
wherein a height of the underlying layer is in a range of 1.0 to 15 μm.

12. The display apparatus according to claim 8,
wherein a radius of curvature of the protrusion is in a range of 3.0 to 100 μm.

13. The display apparatus according to claim 7,
wherein an area of a light-emitting region of the organic electroluminescent element is equal to or smaller than ½ of an area of a bottom surface of the protrusion of the underlying layer.

14. A display apparatus comprising:
an underlying layer formed on a substrate and having a protrusion;
an organic electroluminescent element formed on the protrusion of the underlying layer; and
a lens portion formed on the organic electroluminescent element, the lens portion converging light emitted by the organic electroluminescent element,
wherein a surface of the lens portion has a protruding surface at a position corresponding to that of the protrusion of the underlying layer.

15. The display apparatus according to claim 14,
wherein a protrusion formed on the underlying layer has a hemispherical shape.

16. The display apparatus according to claim 14,
wherein a protrusion formed on the underlying layer has a quadrangular pyramidal frustum shape.

17. The display apparatus according to claim 14,
wherein a width of the underlying layer is in a range of 5.0 to 30 μm.

18. The display apparatus according to claim 14,
wherein a height of the underlying layer is in a range of 1.0 to 15 μm.

19. The display apparatus according to claim 15,
wherein a radius of curvature of the protrusion is in a range of 3.0 to 100 μm.

20. The display apparatus according to claim 14,
wherein an area of a light-emitting region of the organic electroluminescent element is equal to or smaller than ½ of an area of a bottom surface of the protrusion of the underlying layer.
